(19) United States
(12) Patent Application Publication
(10) Pub. No.: US 2014/0035635 A1
(43) Pub. Date: Feb. 6, 2014

(54) APPARATUS FOR GLITCH-FREE CLOCK SWITCHING AND A METHOD THEREOF

(71) Applicants: Srinivas Rao, Bangalore (IN); Gajendra Singh Ranka, Bangalore (IN)

(72) Inventors: Srinivas Rao, Bangalore (IN); Gajendra Singh Ranka, Bangalore (IN)

(73) Assignee: Tejas Networks Limited Plot No. 25, JP Software Park, Bangalore (IN)

(21) Appl. No.: 13/261,745

(22) PCT Filed: Aug. 11, 2011
(86) PCT No.: PCT/IN11/00529

§ 371 Date: Sep. 23, 2013

(30) Foreign Application Priority Data
Mar. 23, 2011 (IN) 897/CHE/2011

(51) Int. Cl. H03L 7/00

(52) U.S. Cl. CPC H03L 7/00
USPC 327/144

(57) ABSTRACT

The invention relates to an apparatus and a method for glitch-free clock switching. In one embodiment this is accomplished by a first clock source, one or more second clock source and a clock switching control device configured to synchronize the receive input clock from the first clock source and the second clock source, and output at least one of the them according to control signal selection.

### FIELD OF THE INVENTION

The present invention generally relates to a system and method for glitch-free switching in redundant systems. This invention describes a method to avoid clock glitches in selecting clocks between a first clock source and one or more second clock source in a redundant system.

### BACKGROUND OF THE INVENTION

In circuit applications, the clock signal is of the extreme importance. In particular, telecommunication switching systems require dependable timing signals to operate properly and to transmit digital data signals that are error free. In order to avoid failures caused by errors such as loss of clock and loss of frame, and to facilitate system fault diagnosis and testing, redundant timing signals may be provided.

In an example domain of telecommunication systems where high-speed data are transmitted, even single bit errors cannot be tolerated. It may be seen that in order to switch from one active clock signal to the other, the clock signals must be fully synchronous in frequency and phase to avoid producing bit errors in the data transmission.

Further, in telecom system, to avoid single points of failure, it is well known method to replicate certain critical sub-systems like power supplies, system clocks, control functions and so on.

However, it is difficult to achieve glitch-free switching of critical system clocks when the system clock generator switches from a first to a second clock source. As per one of the known method of switching evident from Prior art FIG. 1, the selection between the first clock source and second clock source is performed by the sub-system using a simple multiplexor. Since, the selection is independent of the phase of the clocks, when the selection changes, the sub-system clock could exhibit a glitch as shown in Prior art FIG. 2.

This could cause severe problems in the sub-system, particularly in synchronization and other logic. Accordingly, a need has arisen for circuits that closely phase align and switch between two or more timing signals.

### SUMMARY OF THE INVENTION

An aspect of the present invention is to address at least the above-mentioned problems and/or disadvantages and to provide at least the advantages described below.

Accordingly, an aspect of the present invention is to provide a glitch-free switching apparatus comprising a first clock source, at least one second clock source and a clock switching control device configured to synchronize the receive input clock from the first clock source and the second clock source, and output at least one of the them according to control signal selection.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description taken in conjunction with the accompanying drawings in which:

FIG. 1 shows a block diagram of conventional apparatus with clock switching.

FIG. 2 shows timing diagram of conventional apparatus output clock with a glitch.

FIG. 3 shows an apparatus configured with glitch-free clock switching in accordance with one exemplary embodiment of the present invention.

FIG. 4 shows an apparatus configured with glitch free clock switching for high frequency signals in accordance with one exemplary embodiment of the present invention.

FIG. 5 shows timing diagram of glitch-free clock switching of the present invention.

Persons skilled in the art will appreciate that elements in the figures are illustrated for simplicity and clarity and may have not been drawn to scale. For example, the dimensions of some of the elements in the figure may be exaggerated relative to other elements to help to improve understanding of various exemplary embodiments of the present disclosure.

Throughout the drawings, it should be noted that like reference numbers are used to depict the same or similar elements, features, and structures.

### DESCRIPTION OF THE INVENTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions are omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention are provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

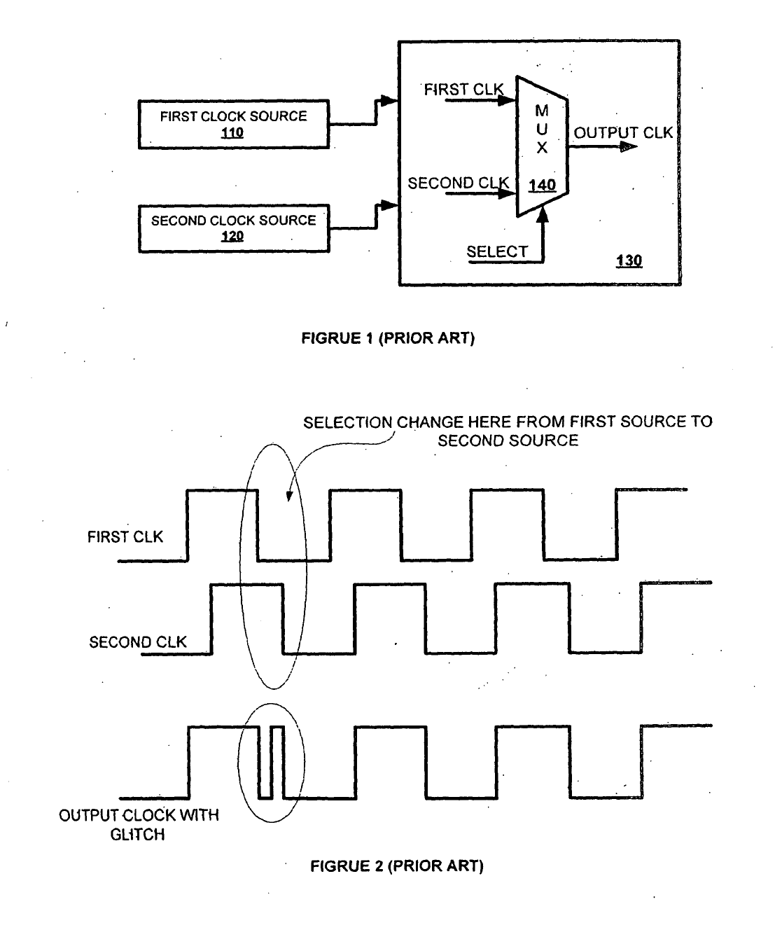

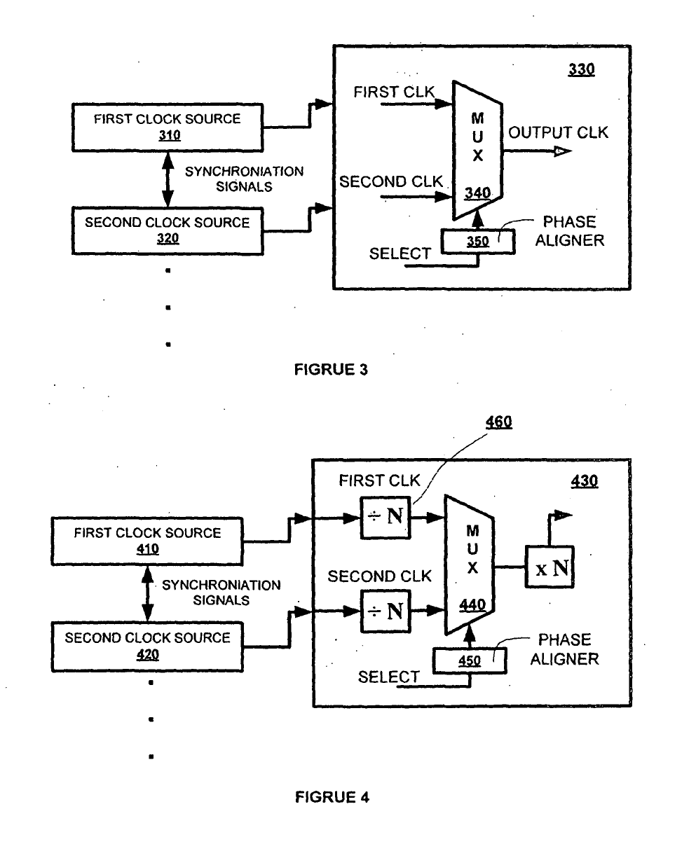

FIGS. 1 through 5, discussed below, and the various embodiments used to describe the principles of the present disclosure in this patent document are by way of illustration only and should not be construed in any way that would limit the scope of the disclosure. Those skilled in the art will understand that the principles of the present disclosure may be implemented in any suitably arranged communications system. The terms used to describe various embodiments are exemplary. It should be understood that these are provided to merely aid the understanding of the description, and that their use and definitions in no way limit the scope of the invention. Terms first, second, and the like are used to differentiate between objects having the same terminology and are in no way intended to represent a chronological order, unless where explicitly stated otherwise. A set is defined as a non-empty set including at least one element.

As shown in FIG. 3, the glitch-free apparatus of the present invention comprises a first clock source, one or more second clock source, and a clock switching control device. The clock switching control device includes a multiplexer, a control signal phase aligner module, a clock select signal source, and a clock output line. Clock sources provide different clock signals to the clock switching control device may switch between in response to commands to switch the clock signal of the circuit. Control inputs, which are used to select one of the clock signals provided by clock sources, are provided to the dock switching control device from clock select signal source. The clock switching control device decodes the control inputs as first clock source or any other second clock source and generates asynchronous outputs. The clock switching control device multiplexes the clock signals from clock sources and outputs one of the clock signals based on the selection. In the present apparatus, the clock sources are phase synchronized.

In the depicted exemplary embodiment, the clock switching control device having two clocks signal inputs, (for example CLK_0, and CLK1). The multiplexer selects one of the two clock input signals as a clock output signal CLK_OUT based on control inputs provided to the multiplexer by clock select signal source. For example, if Selection is first clock source, the multiplexer may select clock input signal CLK_O as the clock output signal CLK_OUT. Similarly, if selection is one of the second clock sources, the multiplexer may select clock input signal CLK_1 as the clock output signal CLK_OUT. It is also possible there may any other possible combinations of selection based on the number of input sources. It should be noted that the inputs to the multiplexer, i.e. CLK_0, CLK_1 . . . CLK_n, are all synchronous with respect to one another before feeding into the clock switching control device. The control signal selection is fed in to the signal phase aligner module, where the signal phase aligner module is capable of receiving the control signal selection as input and outputs the aligned signal to the multiplexer.

For glitch-free switching, the clock select signal source is asserted during the period of the clocks, where the XOR of the clocks is zero (select region). Since the first clock source and one or more second dock source are phase synchronized, the selection logic has to be timed accurately to coincide with the select region, i.e. the clock switching control device switches the primary input to the secondary input in the select region. Further, the control signal selection is also allowed to coincide on the same period of the clock to enable the glitch-free switchover.

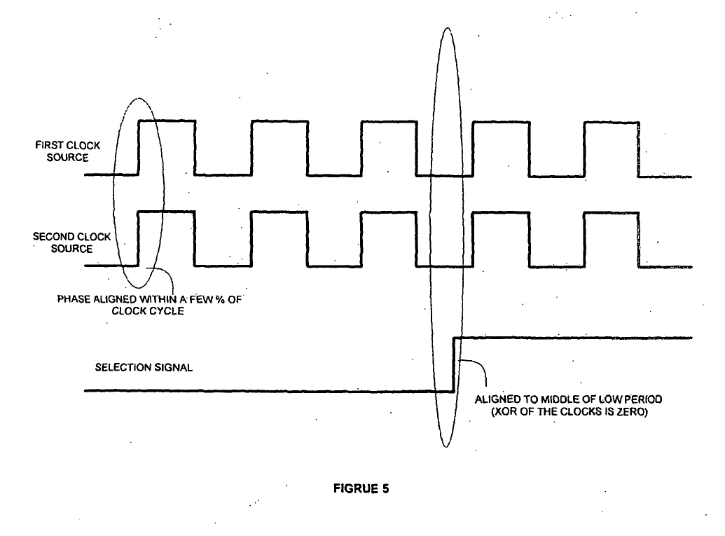

FIG. 4 shows a glitch free apparatus in accordance with exemplary embodiment of the present invention, where the clock signal to be selected is of high frequency and the selection logic cannot be timed accurately to coincide with select region. The selection logic has to be timed accurately to coincide with the select region, a divider means is employed in the apparatus as shown in FIG. 4. To acquire low frequency clock signal the divider means divides the first clock source and the second clock source by an integer factor. The first clock source line employs a first divider or integrator or any other means and the second clock source line employs a second divider or integrator or any other means for dividing the clock. The selection of the clock signal can then happen at the lower frequency clock. In a related aspect, the lower frequency clock can be multiplied by the same integer factor. Since the selection is glitch-free, the multiplied clock output will also be glitch free.

The sequence of operation for selecting the selection signal is as follows. The negative/positive edge on the first/second clock source by a local clock is detected. The selection signal change is then aligned to select region of the divided first/second clock source as shown in FIG. 5. It must be noted that the clock division integer factor, the sub-system clock and the local clock all are system specific and can change according to the requirement. These changes are considered within the scope of the present invention.

The selection signal is asynchronous to first/second clock source. The signal phase aligner module changes the final selection signal to the multiplexer and aligns the final selection signal change to select region of the dividend first/second clock source.

As per one embodiment of the present invention, for glitch-less switch over, synchronization signals are exchanged between the first and second clock sources to ensure that their output clocks are in frequency and phase synchronization. The phases are aligned within a few percentage of clock cycle as shown in FIG. 5.

In an advantageous aspect, the invention prevents clock glitches during the switching from the first to the second clock and vice-versa. Once the clocks are in phase, the switching from the first to the second happens at the select region which completely avoids glitches in the clock switching circuit. The switching from first to second signal is by default as and when a fault occurs.

The architectural framework of the present invention consists of a glitch-free design of a clock switching between a first and second clock source. Further, synchronization and alignment between clock sources and the selection signal is also achieved.

FIGS. 1-5 are merely representational and are not drawn to scale. Certain portions thereof may be exaggerated, while others may be minimized. FIGS. 1-5 illustrate various embodiments of the invention that can be understood and appropriately carried out by those of ordinary skill in the art.

In the foregoing detailed description of embodiments of the invention, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus, the following claims are hereby incorporated into the detailed description of embodiments of the invention, with each claim standing on its own as a separate embodiment.

It is understood that the above description is intended to be illustrative, and not restrictive. It is intended to cover all alternatives, modifications and equivalents as may be included within the spirit and scope of the invention as defined in the appended claims. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein,” respectively.

1. A glitch-free switching apparatus comprising:
a first clock source;
at least one second clock source; and
a clock switching control device configured to synchronize the receive input clock from the first clock source and the second clock source, and output at least one of the them according to control signal selection
wherein the clock switching control device switches the first clock input to the second clock input at the select region and the control signal selection is also allowed to coincide on the same period of the clock to enable the glitch-free switchover.

2. The glitch-free switching apparatus of claim 1, wherein the clock switching control device includes a multiplexer, wherein the multiplexer receives the first clock source, the second clock source and the control signal selection as the input and outputs a glitch-free clock.

3. The glitch-free switching apparatus of claim 1, wherein the clock switching control device further includes a signal phase aligner module, wherein the signal phase aligner module is capable of receiving the control signal selection as input and outputs the aligned signal to the multiplexer.

4. (canceled)

5. The glitch-free switching apparatus of claim 2, wherein the clock switching control device switches the first clock source to the second clock source, where the first clock source or the second clock source frequency is high, then the first clock source and the second clock source inputs is divided by an integer factor and the selection can then happen on the lower frequency clock.

6. The glitch-free switching apparatus of claim 5, wherein the clock switching control device output is a lower frequency clock which is multiplied by the same integer factor to enable the glitch-free switchover.

7. The glitch-free switching apparatus of claim 1 switches between first clock source and second clock source signals in response to detecting specific trigger which includes faults, operator commands etc.

8. The glitch-free switching apparatus of claim 1 wherein the control signal selection is asynchronous to the first and second clock source.

9. The glitch-free switching apparatus of claim 1, wherein the second clock source receives a reference clock from the first clock source.

10. The glitch free switching apparatus of claim 1, wherein the select region is a region where XOR of the first clock source and at least one second clock source is zero.
